(19) United States
(12) Patent Application Publication
(10) Pub. No.: US 2021/0125822 A1
(43) Pub. Date: Apr. 29, 2021

(54) FILM SURFACE TREATMENT METHOD AND FILM SURFACE TREATMENT DEVICE

(71) Applicants: Chengdu BOE Optoelectronics Technology Co., Ltd., Chengdu, Sichuan Province (CN); BOE Technology Group Co., Ltd., Beijing (CN)

(72) Inventors: Zhiguo DENG, Beijing (CN); Zhen WANG, Beijing (CN); Xi YAN, Beijing (CN); Zhao GUO, Beijing (CN); Faye LI, Beijing (CN); Chao HUANG, Beijing (CN); Jie LIU, Beijing (CN); Yan LIU, Beijing (CN); Xianjie LI, Beijing (CN)

(21) Appl. No.: 16/961,329

(22) PCT Filed: Dec. 25, 2019
(86) PCT No.: PCT/CN2019/128322

§ 371 Date: Jul. 10, 2020

(30) Foreign Application Priority Data
Jan. 8, 2019 (CN) 201910014948.5

(51) Int. Cl. H01L 21/02; H01L 21/67

(52) U.S. Cl. CPC H01L 21/02049; H01L 21/67028; H01L 21/02661

(57) ABSTRACT

The disclosure provides a film surface treatment method and a film surface treatment device. By etching a surface of the film with hydrofluoric acid, substances on the surface of the film can be etched away; by cleaning the hydrofluoric acid on the surface, subjected to etching, of the film with a cleaning solution, residual hydrofluoric acid on the surface of the film can be removed, so that over etching to a film caused by the residual hydrofluoric acid can be avoided; and by oxidizing the surface, subjected to cleaning, of the film with ozone water, a compact and uniform oxide layer can be formed on the surface of the film. In this way, the effect of an ELA process can be improved.

### CROSS REFERENCE TO RELATED APPLICATIONS

The present disclosure is National Stage of International Application No. PCT/CN2019/128322, filed Dec. 25, 2019, which claims the priority to a Chinese patent application No. 201910014948.5, filed with the China National Intellectual Property Administration on Jan. 8, 2019, both of which are hereby incorporated by reference in their entireties.

### FIELD

The present disclosure relates to the field of display technology, in particular to a film surface treatment method and a film surface treatment device.

### BACKGROUND

A low temperature poly-silicon thin film transistor (LTPS TFT) process usually involves a process of transforming amorphous silicon (a-Si) into polycrystalline silicon (p-Si) through an excimer laser annealing (ELA) process. In order to improve the effect of the ELA process, it is generally necessary to pretreat the surface of an a-Si film beforehand, so as to generate a silicon oxide film on the surface of the a-Si film. However, varying uneven marks (i.e., Mura) may appear on the surface of the a-Si film during pretreatment, which results in poor uniformity of the generated silicon oxide film, thus affecting the effect of the ELA process and further adversely affecting the performance of a film transistor.

### SUMMARY

An embodiment of the present disclosure provides a film surface treatment method, comprising:

etching a surface of a film with hydrofluoric acid;

cleaning the hydrofluoric acid on the surface, subjected to etching, of the film with a cleaning solution; and

oxidizing the surface, subjected to cleaning, of the film with ozone water to form an oxide layer on the surface of the film.

Optionally, in the embodiment of the present disclosure, after the etching and before the cleaning, the method further comprises: drying the surface, subjected to etching, of the film with a chemically inactive gas.

Optionally, in the embodiment of the present disclosure, after the cleaning and before the oxidizing, the method further comprises: drying the surface, subjected to cleaning, of the film with a chemically inactive gas.

Optionally, in the embodiment of the present disclosure, the cleaning solution is an aqueous solution.

Optionally, in the embodiment of the present disclosure, before the etching the surface of the film with the hydrofluoric acid, the method further comprises: removing impurities on the surface of the film with ozone water.

Correspondingly, an embodiment of the present disclosure also provides a film surface treatment device, comprising a hydrofluoric acid etching chamber, a hydrofluoric acid cleaned chamber, an ozone oxidizing chamber and a bearing pedestal; wherein

an outlet of the hydrofluoric acid etching chamber is connected with an inlet of the hydrofluoric acid cleaned chamber, an outlet of the hydrofluoric acid cleaned chamber is connected with an inlet of the ozone oxidizing chamber, and the bearing pedestal penetrates through the hydrofluoric acid etching chamber, the outlet of the hydrofluoric acid etching chamber, the inlet of the hydrofluoric acid cleaned chamber, the hydrofluoric acid cleaned chamber, the outlet of the hydrofluoric acid cleaned chamber, the inlet of the ozone oxidizing chamber, and the ozone oxidizing chamber;;

the bearing pedestal is configured to bear a substrate on which a film is formed;

the hydrofluoric acid etching chamber is configured to etch a surface of the film with hydrofluoric acid;

the hydrofluoric acid cleaned chamber is configured to clean the hydrofluoric acid on the surface, subjected to etching, of the film with a cleaning solution; and

the ozone oxidizing chamber is configured to oxidize the surface, subjected to cleaning, of the film with ozone water to form an oxide layer on the surface of the film.

Optionally, in the embodiment of the present disclosure, the outlet of the hydrofluoric acid etching chamber is connected with the inlet of the hydrofluoric acid cleaned chamber through a first air knife and a first baffle, wherein the first air knife is on a side, provided with the film, of the bearing pedestal, and the first baffle is on a side, away from the film, of the bearing pedestal; and

the first air knife is configured to blow out a chemically inactive gas with a first preset pressure, separate the hydrofluoric acid etching chamber from the hydrofluoric acid cleaned chamber, and dry the surface, subjected to hydrofluoric acid etching, of the film.

Optionally, in the embodiment of the present disclosure, a first preset included angle is between a direction of the gas blown out by the first air knife and a direction perpendicular to the bearing pedestal, so that the gas blown out by the first air knife inclines towards the hydrofluoric acid etching chamber.

Optionally, in the embodiment of the present disclosure, the outlet of the hydrofluoric acid cleaned chamber is connected with the inlet of the ozone oxidizing chamber through a second air knife and a second baffle, wherein the second air knife is on the side, provided with the film, of the bearing pedestal, and the second baffle is on the side, away from the film, of the bearing pedestal; and

the second air knife is configured to blow out a chemically inactive gas with a second preset pressure, separate the hydrofluoric acid cleaned chamber from the ozone oxidizing chamber, and dry the surface, subjected to cleaning, of the film.

Optionally, in the embodiment of the present disclosure, the second air knife comprises a first sub-air knife and a second sub-air knife which are independent of each other; and

the first sub-air knife is arranged proximate to the outlet of the hydrofluoric acid cleaned chamber, and the second sub-air knife is arranged proximate to the inlet of the ozone oxidizing chamber.

Optionally, in the embodiment of the present disclosure, a second preset included angle is between a direction of the gas blown out by the first sub-air knife and a direction perpendicular to the bearing pedestal, so that the gas blown out by the first sub-air knife inclines towards the hydrofluoric acid cleaned chamber.

Optionally, in the embodiment of the present disclosure, a third preset included angle is between a direction of the gas blown out by the second sub-air knife and a direction perpendicular to the bearing pedestal, so that the gas blown out by the second sub-air knife inclines towards the ozone oxidizing chamber.

### BRIEF DESCRIPTION OF THE DRAWINGS

FIG. 1 is a flowchart of a surface of a film treatment method provided by embodiments of the present disclosure.

FIG. 2 is a schematic structural diagram of a surface of a film treatment device provided by the embodiments of the present disclosure.

FIG. 3 is another schematic structural diagram of the surface of the film treatment device provided by the embodiments of the present disclosure.

### DETAILED DESCRIPTION OF THE EMBODIMENTS

In order to make the purpose, technical scheme and advantages of the present disclosure clearer, the specific implementation of a film surface treatment method and a film surface treatment device provided by the embodiments of the present disclosure will be described in detail below with reference to the accompanying drawings. It should be understood that the preferred embodiments described below are only configured to illustrate and explain the present disclosure, rather than to limit the disclosure. Besides, the embodiments in the present application and the features in the embodiments may be combined with each other without conflict. It should be noted that the sizes and shapes of the figures in the accompanying drawings do not reflect true proportions, and are only for the purpose of schematically illustrating the content of the present disclosure. The same or similar reference numerals refer to the same or similar elements or elements having the same or similar functions throughout.

In the LTPS TFT process, an LTPS TFT is generally prepared on a substrate. When an active layer of the LTPS TFT is prepared, transforming a-Si into p-Si through an ELA process is usually required. However, after an a-Si film is prepared on the substrate, the surface of the a-Si film generally needs to be pretreated before the ELA process, so that a compact and uniform silicon oxide film is generated on the surface of the a-Si film. The silicon oxide film can effectively absorb laser energy in the ELA process, fully melt a-Si, and serve as a heat insulation layer for a-Si in a molten state in the ELA process, so that a-Si is transformed into p-Si with a certain grain size and good uniformity.

Generally, a pretreatment method of the surface of the a-Si film may comprise the following steps. (1) Removing impurities on the surface of the a-Si film with ozone water, so as to remove organic matters that may remain on the surface of the a-Si film, wherein a non-uniform silicon oxide layer may also be formed on the surface of the a-Si film. (2) Etching the surface of the a-Si film with hydrofluoric acid, so as to remove the non-uniform silicon oxide layer formed on the surface of the a-Si film. (3) Oxidizing the surface of the a-Si film with ozone water, so as to form a compact and uniform silicon oxide layer on the surface of the a-Si film. However, during the period from the completion of the step (2) to the start of the step (3), hydrofluoric acid may remain on the surface of the a-Si film due to limited drying capability, which may cause over etching to a-Si, resulting in a Mura phenomenon on the surface of the a-Si film. The Mura phenomenon will lead to poor uniformity of the generated silicon oxide film, thus affecting the effect of the ELA process and further adversely affecting the performance of a film transistor.

In view of this, an embodiment of the present disclosure provides a film surface treatment method configured to avoid the Mura phenomenon on the surface of the a-Si film.

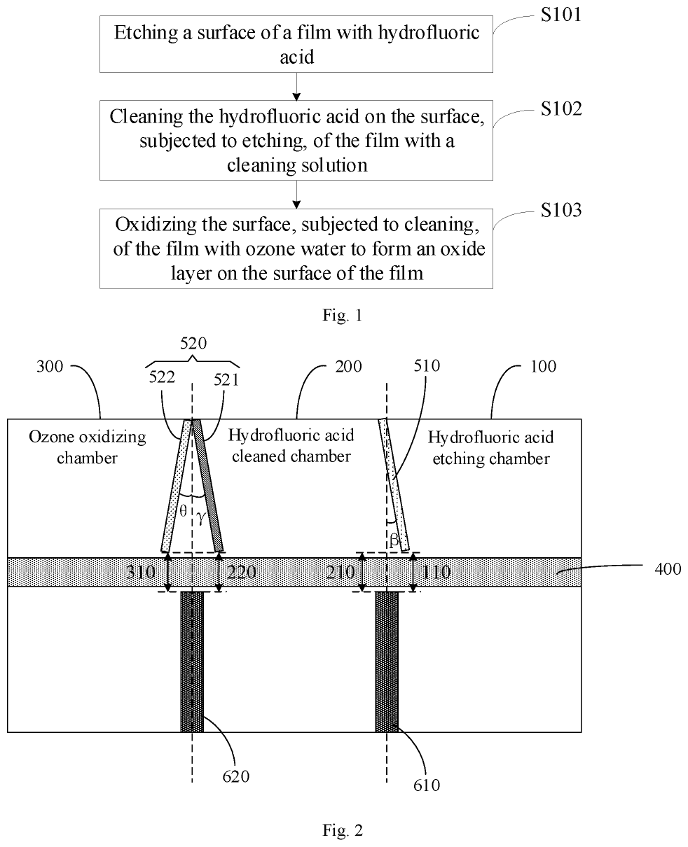

Referring to FIG. 1, the film surface treatment method provided by the embodiment of the present disclosure may comprise the following steps.

S101, etching a surface of a film with hydrofluoric acid.

S102, cleaning the hydrofluoric acid on the surface of the film, subjected to etching, of the film with a cleaning solution.

S103, oxidizing the surface, subjected to cleaning, of the film with ozone water to form an oxide layer on the surface of the film.

According to the film surface treatment method provided by the embodiment of the present disclosure, by etching the surface of the film with the hydrofluoric acid, substances on the surface of the film can be etched away; by cleaning the hydrofluoric acid on the surface, subjected to etching, of the film with the cleaning solution, residual hydrofluoric acid on the surface of the film can be removed, so that over etching to the film caused by the residual hydrofluoric acid can be avoided; and by oxidizing the surface, subjected to cleaning, of the film with the ozone water, the compact and uniform oxide layer can be formed on the surface of the film. In this way, the effect of the ELA process can be improved.

During specific implementation, in the embodiment of the present disclosure, the film may be an a-Si film. In this way, by etching a surface of the a-Si film with hydrofluoric acid, substances on the surface of the a-Si film can be etched away. For example, a non-uniform silicon oxide film can be etched away to expose a-Si. By cleaning the hydrofluoric acid on the surface, subjected to etching, of the a-Si film with the cleaning solution, residual hydrofluoric acid on the surface of the a-Si film can be removed, so that over etching to a-Si caused by the residual hydrofluoric acid can be avoided. By oxidizing the surface, subjected to cleaning, of the a-Si film with ozone water, the compact and uniform silicon oxide layer can be formed on the surface of the a-Si film. In this way, when the ELA process is performed, the effect of the ELA process can be improved, and further, the performance of a prepared film transistor can be improved. Generally, after oxidizing treatment, the a-Si film is transformed into a p-Si film by the ELA process. After the p-Si film is formed, a gate insulating layer is also formed on the p-Si film. In order to optimize the surface of the formed p-Si film, the surface of the p-Si film can also be pretreated after the p-Si film is formed and before the gate insulating layer is formed. During specific implementation, in the embodiments of the present disclosure, the film may also be a p-Si film transformed from an a-Si film. In this case, by etching a surface of the p-Si film with hydrofluoric acid, substances on the surface of the p-Si film can be etched away, so as to expose p-Si; by cleaning the hydrofluoric acid on the surface, subjected to etching, of the p-Si film with a cleaning solution, residual hydrofluoric acid on the surface of the p-Si film can be removed, so that over etching to p-Si caused by the residual hydrofluoric acid can be avoided; and by oxidizing the surface, subjected to cleaning, of the p-Si film with ozone water, the compact and uniform silicon oxide layer can be formed on the surface of the p-Si film, so that the performance of a prepared film transistor can be improved. The following description will take a-Si film as an example for illustration.

During specific implementation, the cleaning solution is configured to clean hydrofluoric acid, and may be, for example, an aqueous solution. In this way, a good cleaning effect can be achieved, and the cost can be reduced. Further, the aqueous solution may be ultrapure water. Of course, in practical application, the cleaning solution can be determined according to the actual application environment, which is not limited herein.

Further, during specific implementation, in the embodiments of the present disclosure, after etching and before cleaning, the method may further comprise: drying the surface, subjected to etching, of the film with a chemically inactive gas. In this way, the residual hydrofluoric acid can be further removed, and over etching to the a-Si film due to the residual hydrofluoric acid can be avoided. In addition, due to using the chemically inactive gas, oxidation caused by the contact of the film, subjected to etching, with air can also be avoided.

Further, during specific implementation, in the embodiment of the present disclosure, after cleaning and before oxidizing, the method may further comprise: drying the surface, subjected to cleaning, of the film with a chemically inactive gas. In this way, the cleaning solution can be removed, and oxidation caused by the contact of the a-Si film, subjected to etching, with air can also be avoided.

Further, during specific implementation, the chemically inactive gas may include at least one of inert gas or nitrogen.

In the preparation process, impurities such as organic matters may remain on the surface of the film. During specific implementation, in the embodiments of the present disclosure, before etching the surface of the film with the hydrofluoric acid, the method may further comprise: removing impurities on the surface of the film with ozone water. In this way, the impurities (e.g., organic matters) that may remain on the surface of the a-Si film can be removed. Of course, the residual impurities may also be other substances, which depends on the actual application environment and is not limited herein.

The film surface treatment method provided by the embodiments of the present disclosure is described below with a specific example, but the reader should know that the specific process is not limited to the following description. In the below description, the film is an a-Si film, and the chemically inactive gas is nitrogen.

The film surface treatment method provided by the embodiment of the present disclosure may comprise the following steps.

(1) Removing organic matters on a surface of the a-Si film with ozone water, so as to remove organic matters that may remain on the surface of the a-Si film, wherein a non-uniform silicon oxide layer may also be formed on the surface of the a-Si film.

(2) Etching the surface of the a-Si film with hydrofluoric acid, so as to remove the non-uniform silicon oxide layer formed on the surface of the a-Si film.

(3) Drying the surface, subjected to etching, of the a-Si film with nitrogen, so as to remove residual hydrofluoric acid, and also prevent air from oxidizing the surface of the a-Si film.

(4) Cleaning the hydrofluoric acid on the surface, subjected to drying in the step (3), of the a-Si film with an aqueous solution, so as to remove residual hydrofluoric acid on the surface of the a-Si film, thus avoiding over etching to a-Si caused by the residual hydrofluoric acid, wherein a water film may also be formed on the surface of the a-Si film, thus further ensuring the purity of the process.

(5) Drying the surface, subjected to cleaning, of the a-Si film with nitrogen, so as to remove residual aqueous solution.

(6) Oxidizing the surface, subjected to drying in the step (5), of the a-Si film with ozone water, so as to form a compact and uniform silicon oxide layer on the surface of the a-Si film, thus improving the effect of the ELA process when the ELA process is performed, and further improving the performance of a prepared thin film transistor.

Based on the same inventive concept, an embodiment of the present disclosure also provides a film surface treatment device, as shown in FIG. 2, which may comprise a hydrofluoric acid etching chamber 100, a hydrofluoric acid cleaned chamber 200, an ozone oxidizing chamber 300, and a bearing pedestal 400, wherein an outlet 110 of the hydrofluoric acid etching chamber 100 is connected with an inlet 210 of the hydrofluoric acid cleaned chamber 200, an outlet 220 of the hydrofluoric acid cleaned chamber 200 is connected with an inlet 310 of the ozone oxidizing chamber 300, the bearing pedestal 400 penetrates through the hydrofluoric acid etching chamber 100 and the outlet 110 thereof, the hydrofluoric acid cleaned chamber 200 and the inlet 210 and outlet 220 thereof, and the ozone oxidizing chamber 300 and the inlet 310 thereof, and the bearing pedestal 400 is configured to bear a substrate on which a film is formed.

The hydrofluoric acid etching chamber 100 is configured to etch a surface of a film with hydrofluoric acid.

The hydrofluoric acid cleaned chamber 200 is configured to clean the hydrofluoric acid on the surface, subjected to etching, of the film with a cleaning solution.

The ozone oxidizing chamber 300 is configured to oxidize the surface, subjected to cleaning, of the film with ozone water to form an oxide layer on the surface of the film.

According to the film surface treatment device provided by the embodiment of the present disclosure, the substrate on which the film is formed is arranged on the bearing pedestal, and the substrate sequentially passes through the hydrofluoric acid etching chamber, the hydrofluoric acid cleaned chamber and the ozone oxidizing chamber. When the substrate is in the hydrofluoric acid etching chamber, the surface of the film is etched with hydrofluoric acid, so that substances on the surface of the film can be etched away. When the substrate is in the hydrofluoric acid cleaned chamber, the hydrofluoric acid on the surface, subjected to etching, of the film can be cleaned with a cleaning solution, so that the residual hydrofluoric acid on the surface of the film can be removed, and over etching to the film caused by the residual hydrofluoric acid can be avoided. When the substrate is in the ozone oxidizing chamber, the surface, subjected to cleaning, of the film can be oxidized with ozone water, so that a compact and uniform oxide layer can be formed on the surface of the film. In this way, the effect of the ELA process can be improved when the ELA process is performed.

Generally, an air knife is a device specially designed to blow out strong and high-speed airflow to remove dust, blow-dry water stains and reduce temperature. The airflow blown out by the air knife can be composed of high-strength and uniform laminar airflow. During specific implementation, in the embodiment of the present disclosure, as shown in FIG. 2, the outlet 110 of the hydrofluoric acid etching chamber 100 and the inlet 210 of the hydrofluoric acid cleaned chamber 200 are connected through a first air knife 510 and a first baffle 610. The first air knife 510 is located on a side, provided with the film, of the bearing pedestal 400, and the first baffle 610 is located on a side, away from the film, of the bearing pedestal 400, so as to separate the hydrofluoric acid etching chamber 100 from the hydrofluoric acid cleaned chamber 200. The first air knife 510 is configured to blow out a chemically inactive gas with a first preset pressure, separate the hydrofluoric acid etching chamber 100 from the hydrofluoric acid cleaned chamber 200, and dry the surface, subjected to hydrofluoric acid etching, of the film.

Specifically, the structure of the first air knife can be basically the same as that in the related art, which should be understood by those of ordinary skill in the art, and will not be described in detail herein, nor should it be taken as a limitation to the present disclosure.

During specific implementation, the gas blown out by the first air knife is configured as a barrier between the hydrofluoric acid etching chamber 100 on the side, provided with the film, of the bearing pedestal and the hydrofluoric acid cleaned chamber 200 on the side, provided with the film, of the bearing pedestal, so as to separate the hydrofluoric acid in the hydrofluoric acid etching chamber 100 from the cleaning solution in the hydrofluoric acid cleaned chamber 200. In addition, air can be prevented from entering the hydrofluoric acid etching chamber 100 and the hydrofluoric acid cleaned chamber 200, so that the a-Si film can be prevented from being oxidized by air in the process of entering the hydrofluoric acid cleaned chamber 200 from the hydrofluoric acid etching chamber 100. In addition, the gas blown out by the first air knife can also make a chemically inactive gas available in the hydrofluoric acid cleaned chamber 200, thereby preventing a-Si from being oxidized by air in the process of cleaning hydrofluoric acid. In practical application, since different application environments have different demands on the pressure of the gas blown out by the first air knife, the first preset pressure can be determined according to the actual application environment, which is not limited herein.

Further, in order to prevent the hydrofluoric acid in the hydrofluoric acid etching chamber 100 from entering the hydrofluoric acid cleaned chamber 200, during specific implementation, as shown in FIG. 2, a first preset included angle β is formed between a direction of the gas blown out by the first air knife 510 and a direction perpendicular to the bearing pedestal, so that the gas blown out by the first air knife 510 inclines towards the hydrofluoric acid etching chamber 100. In this way, the hydrofluoric acid in the hydrofluoric acid etching chamber 100 can be further prevented from entering the hydrofluoric acid cleaned chamber 200. In practical application, since different application environments have different demands on the first preset included angle β, the first preset included angle β can be determined according to the actual application environment, which is not limited herein.

During specific implementation, in the embodiment of the present disclosure, as shown in FIG. 2, the outlet 220 of the hydrofluoric acid cleaned chamber 200 and the inlet 310 of the ozone oxidizing chamber 300 are connected through a second air knife 520 and a second baffle 620. The second air knife 520 is located on the side, provided with the film, of the bearing pedestal 400, and the second baffle 620 is located on the side, away from the film, of the bearing pedestal 400, so as to separate the ozone oxidizing chamber 300 from the hydrofluoric acid cleaned chamber 200. The second air knife 520 is configured to blow out a chemically inactive gas with a second preset pressure, separate the hydrofluoric acid cleaned chamber 200 on the side, provided with the film, of the bearing pedestal from the ozone oxidizing chamber 300 on the side, provided with the film, of the bearing pedestal, and dry the surface, subjected to cleaning, of the film. Further, the second air knife 520 may comprise a first sub-air knife 521 and a second sub-air knife 522 which are independent of each other, wherein the first sub-air knife 521 is arranged proximate to the outlet 220 of the hydrofluoric acid cleaned chamber 200, and the second sub-air knife 522 is arranged proximate to the inlet 310 of the ozone oxidizing chamber 300.

During specific implementation, the gas blown out by the first sub-air knife 521 and the second sub-air knife 522 is configured as a barrier between the hydrofluoric acid cleaned chamber 200 on the side, provided with the film, of the bearing pedestal and the ozone oxidizing chamber 300 on the side, provided with the film, of the bearing pedestal, so as to separate the cleaning solution in the hydrofluoric acid cleaned chamber 200 from the ozone water in the ozone oxidizing chamber 300. In addition, air can be prevented from entering the ozone oxidizing chamber 300 and the hydrofluoric acid cleaned chamber 200, so that the a-Si film can be prevented from being oxidized by air in the process of entering the ozone oxidizing chamber 300 from the hydrofluoric acid cleaned chamber 200. In addition, the gas blown out by the first sub-air knife 521 and the second sub-air knife 522 can also make a chemically inactive gas available in the hydrofluoric acid cleaned chamber 200, thereby preventing a-Si from being oxidized by air in the process of cleaning hydrofluoric acid. In practical application, since different application environments have different demands on the pressure of the gas blown out by the first sub-air knife 521 and the second sub-air knife 522, the second preset pressure can be determined according to the actual application environment, which is not limited herein. In addition, the structures of the first sub-air knife 521 and the second sub-air knife 522 may be basically the same as the structure in the related art, which should be understood by those of ordinary skill in the art, and are not described in detail herein, nor should they be taken as a limitation to the present disclosure.

Further, in order to prevent the cleaning solution in the hydrofluoric acid cleaned chamber 200 from entering the ozone oxidizing chamber 300, during specific implementation, as shown in FIG. 2, a second preset included angle γ is formed between a direction of the gas blown out by the first sub-air knife 521 and a direction perpendicular to the bearing pedestal 400, so that the gas blown out by the first sub-air knife 521 inclines towards the hydrofluoric acid cleaned chamber 200. In this way, the cleaning solution in the hydrofluoric acid cleaned chamber 200 can be further prevented from entering the ozone oxidizing chamber 300. In practical application, since different application environments have different demands on the second preset included angle γ, the second preset included angle γ can be determined according to the actual application environment, which is not limited herein.

Further, in order to prevent the ozone water in the ozone oxidizing chamber 300 from entering the hydrofluoric acid cleaned chamber 200, during specific implementation, as shown in FIG. 2, a third preset included angle θ is formed between a direction of the gas blown out by the second sub-air knife 522 and a direction perpendicular to the bearing pedestal 400, so that the gas blown out by the second sub-air knife 522 inclines towards the ozone oxidizing chamber 300. In this way, the ozone water in the ozone oxidizing chamber 300 can be further prevented from entering the hydrofluoric acid cleaned chamber 200. In practical application, since different application environments have different demands on the third preset included angle θ, the third preset included angle θ can be determined according to the actual application environment, which is not limited herein.

Further, the first sub-air knife 521 and the second sub-air knife 522 may be closely arranged to separate the hydrofluoric acid cleaned chamber 200 from the ozone oxidizing chamber 300.

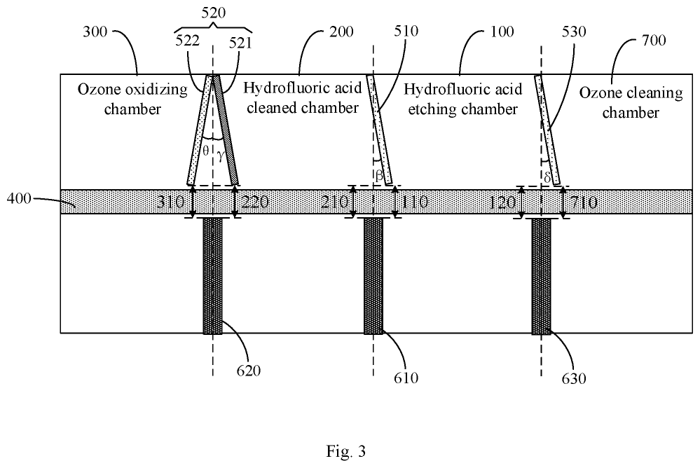

Further, during specific implementation, as shown in FIG. 3, the film surface treatment device may further comprise an ozone cleaning chamber 700. An outlet 710 of the ozone cleaning chamber 700 is connected to an inlet 120 of the hydrofluoric acid etching chamber 100. The ozone cleaning chamber 700 is configured to remove impurities on the surface of the film by ozone water. Further, the outlet 710 of the ozone cleaning chamber 700 and the inlet 120 of the hydrofluoric acid etching chamber 100 are connected through a third air knife 530 and a third baffle 630. The third air knife 530 is located on the side, provided with the film, of the bearing pedestal 400, and the third baffle 630 is located on the side, away from the film, of the bearing pedestal 400, so as to separate the hydrofluoric acid etching chamber 100 from the ozone cleaning chamber 700. The third air knife 530 is configured to blow out a chemically inactive gas with a fourth preset pressure and separate the hydrofluoric acid etching chamber 100 from the ozone cleaning chamber 700. Specifically, the structure of the third air knife can be basically the same as that in the related art, which should be understood by those of ordinary skill in the art, and is not described in detail herein, nor should it be taken as a limitation to the present disclosure. In practical application, since different application environments have different demands on the pressure of the gas blown out by the third air knife, the fourth preset pressure can be determined according to the actual application environment, which is not limited herein.

The working process of the film surface treatment device provided by the embodiment of the present disclosure is described below with a specific example, but the reader should know that the specific process is not limited to the following description. In the below description, the film is an a-Si film, and the chemically inactive gas is nitrogen.

The working process of the film surface treatment device provided by the embodiment of the present disclosure may comprise the following steps.

(1) A substrate on which an a-Si film is formed is put on the bearing pedestal 400 in the ozone cleaning chamber 700, ozone water is generated in the ozone cleaning chamber 700, and organic matters on an surface of the a-Si film are removed with the ozone water, so that organic matters that may remain on the surface of the a-Si film can be removed, wherein a non-uniform silicon oxide layer may also be formed on the surface of the a-Si film.

(2) The substrate treated in the step (1) passes through the third air knife 530, and since the third air knife 530 can blow out nitrogen with the fourth preset pressure, the a-Si film on the substrate can be dried.

(3) The substrate treated in the step (2) is put on the bearing pedestal 400 in the hydrofluoric acid etching chamber 100, and hydrofluoric acid is generated in the hydrofluoric acid etching chamber 100 so as to etch the surface of the a-Si film, thus removing the non-uniform silicon oxide layer on the surface of the a-Si film.

(4) The substrate treated in the step (3) passes through the first air knife 510, and since the first air knife 510 can blow out nitrogen with the first preset pressure, the surface, subjected to etching, of the a-Si film can be dried with the nitrogen so as to remove possible residual hydrofluoric acid, and air can also be prevented from oxidizing the surface of the a-Si film.

(5) The substrate treated in the step (4) is put on the bearing pedestal 400 in the hydrofluoric acid cleaned chamber 200, and an aqueous solution is generated in the hydrofluoric acid cleaned chamber 200 so as to clean the hydrofluoric acid on the surface of the a-Si film dried in the step (4), thus removing residual hydrofluoric acid on the surface of the a-Si film and avoiding over etching to a-Si caused by the residual hydrofluoric acid, wherein a water film may also be formed on the surface of the a-Si film, thus ensuring the purity of the process.

(6) The substrate treated in the step (5) passes through the first sub-air knife 521 and the second sub-air knife 522 in sequence, and since the first sub-air knife 521 can blow out nitrogen with the second preset pressure, and the second sub-air knife 522 can blow out nitrogen with the third preset pressure, the surface, subjected to cleaning, of the a-Si film can be dried with the nitrogen, so as to remove residual aqueous solution.

(7) The surface of the a-Si film dried in the step (6) is oxidized with ozone water, so as to form a compact and uniform silicon oxide layer on the surface of the a-Si film, thus improving the effect of the ELA process when the ELA process is performed, and further improving the performance of a prepared thin film transistor.

It should be noted that the bearing pedestal may be an automatically rotating pedestal or may be a manually rotating pedestal, which is not limited herein.

According to the film surface treatment method and the film surface treatment device provided by the embodiments of the present disclosure, by etching the surface of the film with the hydrofluoric acid, substances on the surface of the film can be etched away; by cleaning the hydrofluoric acid on the surface, subjected to etching, of the film with the cleaning solution, residual hydrofluoric acid on the surface of the film can be removed, so that over etching to the film caused by the residual hydrofluoric acid can be avoided; and by oxidizing the surface, subjected to cleaning, of the film with the ozone water, the compact and uniform oxide layer can be formed on the surface of the film. In this way, the effect of the ELA process can be improved when the ELA process is performed.

Obviously, those skilled in the art can make various changes and modifications to the present disclosure without departing from the spirit and scope of the present disclosure. Thus, the present disclosure is also intended to comprise these changes and modifications if these changes and modifications fall within the scope of the claims of the present disclosure and equivalent technologies thereof.

1. A film surface treatment method, comprising:
etching a surface of a film with hydrofluoric acid;
cleaning the hydrofluoric acid on the surface, subjected to etching, of the film with a cleaning solution; and
oxidizing the surface, subjected to cleaning, of the film with ozone water to form an oxide layer on the surface of the film.

2. The film surface treatment method according to claim 1, wherein after said etching and before said cleaning, the method further comprises: drying the surface, subjected to etching, of the film with a chemically inactive gas.

3. The film surface treatment method according to claim 1, wherein after said cleaning and before said oxidizing, the method further comprises: drying the surface, subjected to cleaning, of the film with a chemically inactive gas.

4. The film surface treatment method according to claim 1, wherein the cleaning solution is an aqueous solution.

5. The film surface treatment method according to claim 1, wherein before said etching the surface of the film with the hydrofluoric acid, the method further comprises:
removing impurities on the surface of the film with the ozone water.

6. A film surface treatment device, comprising:
a hydrofluoric acid etching chamber;
a hydrofluoric acid cleaned chamber;
an ozone oxidizing chamber; and
a bearing pedestal, wherein
an outlet of the hydrofluoric acid etching chamber is connected with an inlet of the hydrofluoric acid cleaned chamber, an outlet of the hydrofluoric acid cleaned chamber is connected with an inlet of the ozone oxidizing chamber, and the bearing pedestal penetrates through the hydrofluoric acid etching chamber, the outlet of the hydrofluoric acid etching chamber, the inlet of the hydrofluoric acid cleaned chamber, the hydrofluoric acid cleaned chamber, the outlet of the hydrofluoric acid cleaned chamber, the inlet of the ozone oxidizing chamber, and the ozone oxidizing chamber;
the bearing pedestal is configured to bear a substrate on which a film is formed;
the hydrofluoric acid etching chamber is configured to etch a surface of the film with hydrofluoric acid;
the hydrofluoric acid cleaned chamber is configured to clean the hydrofluoric acid on the surface, subjected to etching, of the film with a cleaning solution; and
the ozone oxidizing chamber is configured to oxidize the surface, subjected to cleaning, of the film with ozone water to form an oxide layer on the surface of the film.

7. The film surface treatment device according to claim 6, wherein the outlet of the hydrofluoric acid etching chamber is connected with the inlet of the hydrofluoric acid cleaned chamber through a first air knife and a first baffle; the first air knife is on a side, provided with the film, of the bearing pedestal, and the first baffle is on a side, away from the film, of the bearing pedestal; and
the first air knife is configured to blow out a chemically inactive gas with a first preset pressure, separate the hydrofluoric acid etching chamber from the hydrofluoric acid cleaned chamber, and dry the surface, subjected to hydrofluoric acid etching, of the film.

8. The film surface treatment device according to claim 7, wherein a first preset included angle is between a direction of the gas blown out by the first air knife and a direction perpendicular to the bearing pedestal, so that the gas blown out by the first air knife inclines towards the hydrofluoric acid etching chamber.

9. The film surface treatment device according to claim 6, wherein the outlet of the hydrofluoric acid cleaned chamber is connected with the inlet of the ozone oxidizing chamber through a second air knife and a second baffle; the second air knife is on the side, provided with the film, of the bearing pedestal, and the second baffle is on the side, away from the film, of the bearing pedestal; and
the second air knife is configured to blow out a chemically inactive gas with a second preset pressure, separate the hydrofluoric acid cleaned chamber from the ozone oxidizing chamber, and dry the surface, subjected to cleaning, of the film.

10. The film surface treatment device according to claim 9, wherein the second air knife comprises a first sub-air knife and a second sub-air knife which are independent of each other; and
the first sub-air knife is arranged proximate to the outlet of the hydrofluoric acid cleaned chamber, and the second sub-air knife is arranged proximate to the inlet of the ozone oxidizing chamber.

11. The film surface treatment device according to claim 10, wherein a second preset included angle is between a direction of the gas blown out by the first sub-air knife and a direction perpendicular to the bearing pedestal, so that the gas blown out by the first sub-air knife inclines towards the hydrofluoric acid cleaned chamber.

12. The film surface treatment device according to claim 10, wherein a third preset included angle is between a direction of the gas blown out by the second sub-air knife and a direction perpendicular to the bearing pedestal, so that the gas blown out by the second sub-air knife inclines towards the ozone oxidizing chamber.

13. The film surface treatment method according to claim 2, wherein the cleaning solution is an aqueous solution.

14. The film surface treatment method according to claim 3, wherein the cleaning solution is an aqueous solution.

15. The film surface treatment method according to claim 2, wherein before said etching the surface of the film with the hydrofluoric acid, the method further comprises:
removing impurities on the surface of the film with the ozone water.

16. The film surface treatment method according to claim 3, wherein before said etching the surface of the film with the hydrofluoric acid, the method further comprises:
removing impurities on the surface of the film with the ozone water.
